(19) United States
(12) Patent Application Publication
(10) Pub. No.: US 2010/0053852 A1
(43) Pub. Date: Mar. 4, 2010

(54) Display Device

(75) Inventors: Chi-Ming Tseng, Taipei Hsien (TW); Shyue-Yeou Lu, Taipei Hsien (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHENG UEI PRECISION INDUSTRY CO., LTD., Taipei Hsien (TW)

(21) Appl. No.: 12/203,001

(22) Filed: Sep. 2, 2008

(51) Int. Cl. H05K 7/00

(52) U.S. Cl. 361/679.01

(57) ABSTRACT

A display device is disclosed that includes a frame assembly. A first screen panel and a second screen panel are assembled together with the frame assembly and electrically coupled with each other. A main circuit board electrically connected with both the first and second screen panels defines a receiving opening upon which an underside of the second screen panel is rested. A gap is defined between the second screen panel and the main circuit board when the underside of the second screen panel is rested upon the receiving opening of the main circuit board. Wherein the frame assembly has at least one positioning member configured to be inserted into the gap for restraining the second screen panel in place.

### BACKGROUND OF THE INVENTION

1. Field of the Invention

This present invention relates to a display device, and more specifically to a dual-screen display device.

2. The Related Art

Conventionally, a dual-screen display device includes a main screen panel, a secondary screen panel, a backlight module and a frame assembly. The main screen panel, the secondary screen panel and the backlight module are fixed in the frame assembly.

An auxiliary tool is used to assemble the secondary screen panel in the frame assembly, so that in the process of assembling the dual-screen display device, some incoming dust will most likely pollute the dual-screen display device. Besides, by using the auxiliary tool, the cost of manufacturing the dual-screen display device is raised.

### SUMMARY OF THE INVENTION

An object of the invention is to provide an improved display device that is assembled without any auxiliary tool. The display device includes a frame assembly. A first screen panel and a second screen panel are assembled together with the frame assembly and electrically coupled with each other. A main circuit board electrically connected with both the first and second screen panels defines a receiving opening upon which an underside of the second screen panel is rested. A gap is defined between the second screen panel and the main circuit board when the underside of the second screen panel is rested upon the receiving opening of the main circuit board. Wherein the frame assembly has at least one positioning member configured to be inserted into the gap for restraining the second screen panel in place.

According to above description, since the positioning member of the frame assembly being inserted into the gap defined between the second screen panel and the main circuit board, the process of assembling the second screen panel on the frame assembly is simple. It is obvious that the assembly process of the second screen panel on the frame assembly doesn't need any auxiliary tool, so the cost of manufacturing the display device is reduced and the time of assembling the display device is cut down.

### BRIEF DESCRIPTION OF THE DRAWINGS

The invention, together with its objects and the advantages thereof may be best understood by reference to the following description taken in conjunction with the accompanying drawings, in which:

FIG. 1 is a perspective view of a first embodiment of a dual-screen display device;

FIG. 2 is an exploded perspective view of the dual-screen display device;

FIG. 3 is a perspective view of a first frame of the dual-screen display device shown in FIG. 1;

FIG. 4 is a partially enlarged view of the encircled portion labeled II of FIG. 3;

FIG. 5 is an assembled perspective view of a main circuit board, a main screen panel and a secondary screen panel of the dual-screen display device;

FIG. 6 is an assembled perspective view of the dual-screen display device;

FIG. 7 is a cross-sectional view taken along line VII-VII of FIG. 1;

FIG. 8 is a perspective view of a second embodiment of a dual-screen display device;

FIG. 9 is an exploded perspective view of the dual-screen display device of FIG. 8;

FIG. 10 is a perspective view of a main frame of the dual-screen display device of FIG. 8; and

FIG. 11 is a cross-sectional view taken along line XI-XI of FIG. 8.

### DETAILED DESCRIPTION OF THE PREFERRED EMBODIMENTS

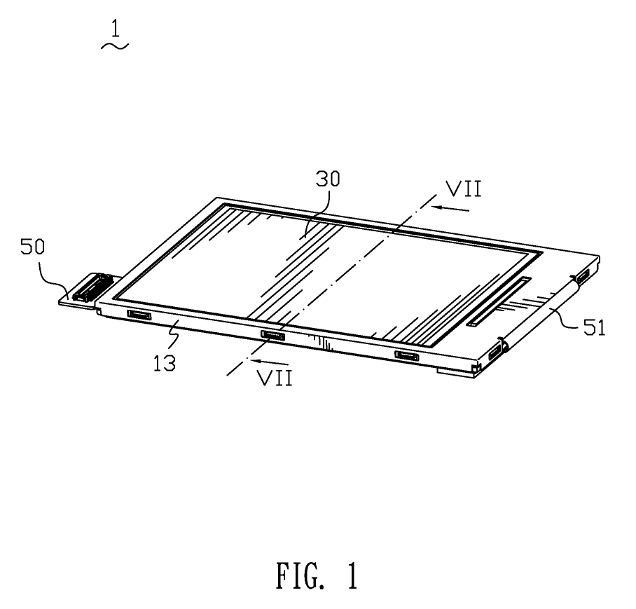

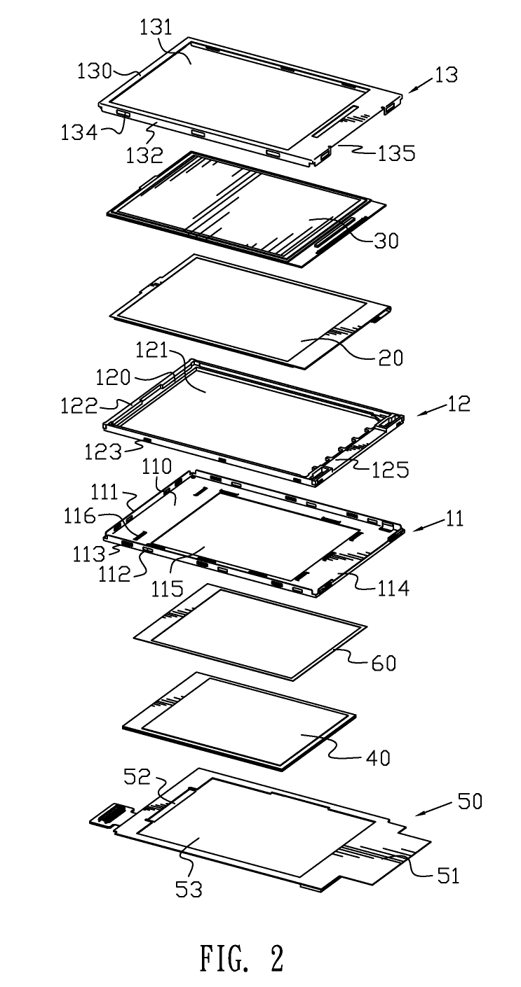

First referring to FIGS. 1 and 2, in a first embodiment of the present invention, a dual-screen display device 1 has a frame assembly, a main screen panel 30, a backlight module 20 and a secondary screen panel 40 all of which are fixed on the frame assembly. The frame assembly contains a first frame 11, a second frame 12 and a third frame 13.

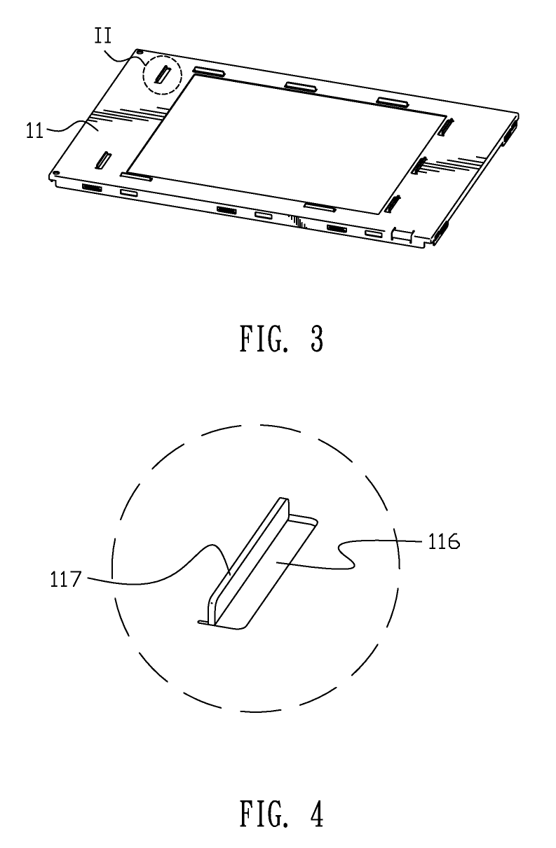

Referring to FIGS. 2-4, the first frame 11 has a rectangular base board 110. Each side of the base board 110 extends upward vertically to form a side wall 111. A plurality of grooves 112 and bulges 113 are formed on the side wall 111. One of the side walls 111 defines an outer opening 114 passing therethrough. The middle portion of the base board 110 defines an opening 115 in rectangular shape. A plurality of auxiliary slots 116 is formed in the base board 110 around the opening 115. An outer edge of the auxiliary slot 116 extends vertically downwardly to form a resisting wall 117 showing a long and narrow piece shape. A twin adhesive tape 60 is glued on the backside of the base board 110 along inner sides of the resisting walls 117.

Referring to FIG. 2, the second frame 12 made of resin material is arranged in the first frame 11. The second frame 12 has four rims 120 defined at its periphery, and these rims 120 define cooperatively a first rectangular space 121. All outer edges of the rims 120 extend vertically upward to form a side wall 122 respectively. One of the side walls 122 defines an inner opening 125 passing therethrough corresponding to the outer opening 114 of the first frame 11. The side walls 122 project outside to form a plurality of protrusions 123 engaged with the grooves 112 of the first frame 11.

The third frame 13 is covered on the first frame 11 such that the second frame 12 is received in the first frame 11 and disposed between the first frame 11 and the third frame 13. The third frame 13 has four side plates 130 which define a second rectangular space 131. Each side plate 130 extends vertically downward to form a side wall 132. Each side wall 132 defines a plurality of slots 134 corresponding to the bulges 113 of the first frame 11. One of the side walls 132 defines a notch 135 passing therethrough and corresponding to the outer opening 114.

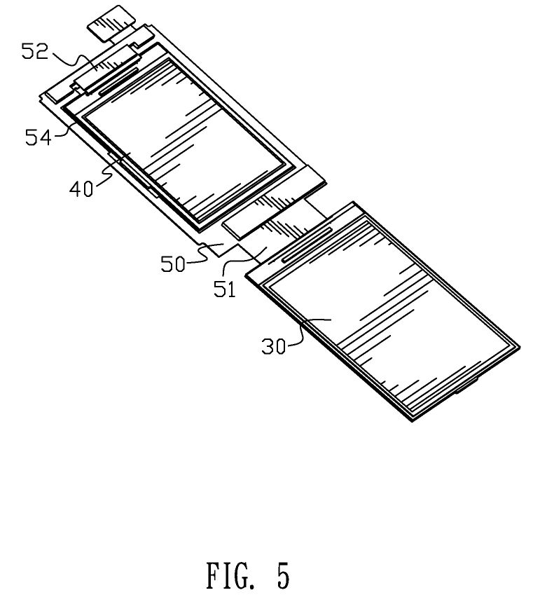

Referring to FIGS. 2 and 5, the main screen panel 30 and the secondary screen panel 40 are connected with a main circuit board 50. The main circuit board 50 is a flexible printed circuit board in the first embodiment. The middle portion of the main circuit board 50 forms a receiving opening 53 in rectangular shape for receiving the secondary screen panel 40 thereupon. One end of the main circuit board 50 has a main connecting portion 51 which is used to connect with the main screen panel 30, and the other end of the main circuit board 50 defines a secondary connecting portion 52 used to connect with the secondary screen panel 40. Some signal wires (not shown) are arranged in the main connecting portion 51 and the secondary connecting portion 52. When the secondary screen panel 40 and the main circuit board 50 are arranged at the backside of the base board 110, the resisting walls 117 are located in a gap 54 defined between the secondary screen panel 40 and the main circuit board 50.

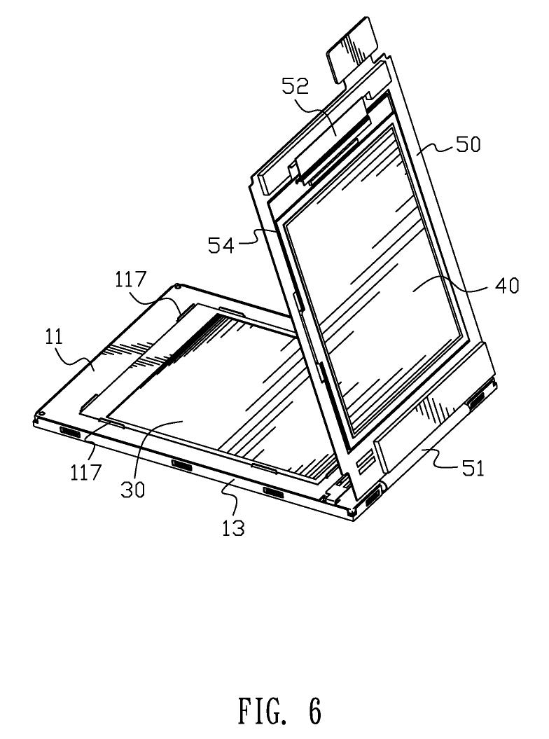

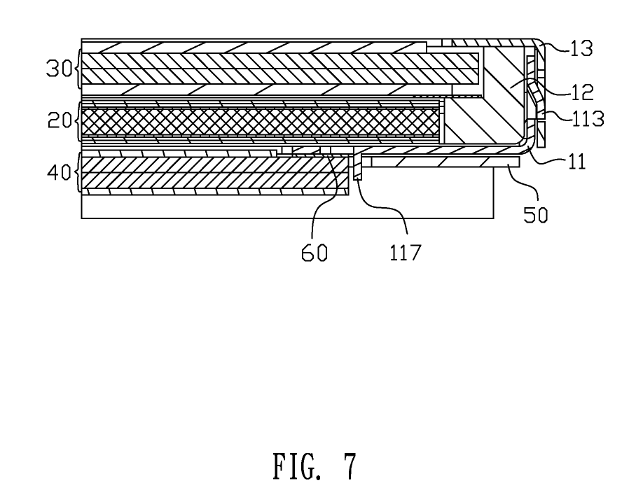

Please refer to FIGS. 2, 5, 6, and 7. In assembling the dual-screen display device 1 of the first embodiment, firstly, the second frame 12 is assembled in the first frame 11. The protrusions 123 are fixed in the grooves 112 of the first frame 11. Then, the backlight module 20 is arranged in the first rectangular space 121 of the second frame 12. Edges of the backlight module 20 respectively resist against edges of the opening 115. Next, the main screen panel 30 is arranged on the backlight module 20 and adhered together with the rims 120. The third frame 13 is covered on the first frame 11 and the second frame 12. The side walls 132 of the third frame 13 cover the side walls 111 of the first frame 11, and the bulges 113 are engaged in the slots 134, so the first frame 11, the second frame 12 and the third frame 13 are assembled together. Finally, the secondary screen panel 40 is fixed on the backside of the base board 110. The main connecting portion 51 of the main circuit board 50 is received in a channel which is defined by the outer opening 114, the inner opening 125 and the notch 135. The secondary screen panel 40 resists the resisting walls 117 and is glued to the twin adhesive tape 60, and then the resisting walls 117 are arranged between the main circuit board 50 and the secondary screen panel 40 to locate the secondary screen panel 40.

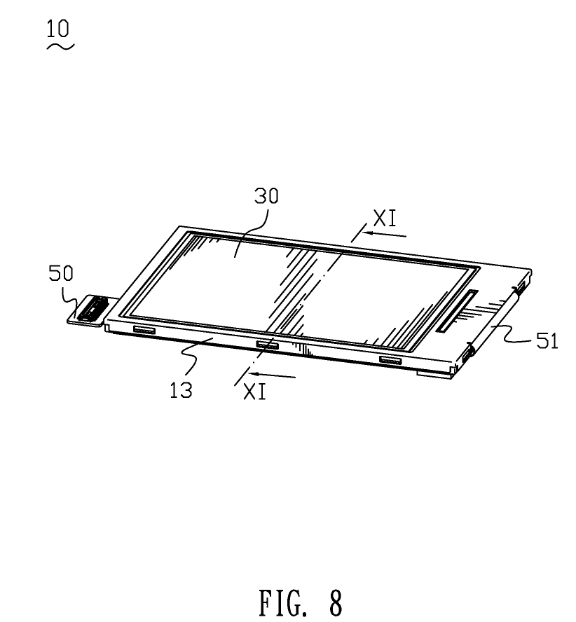

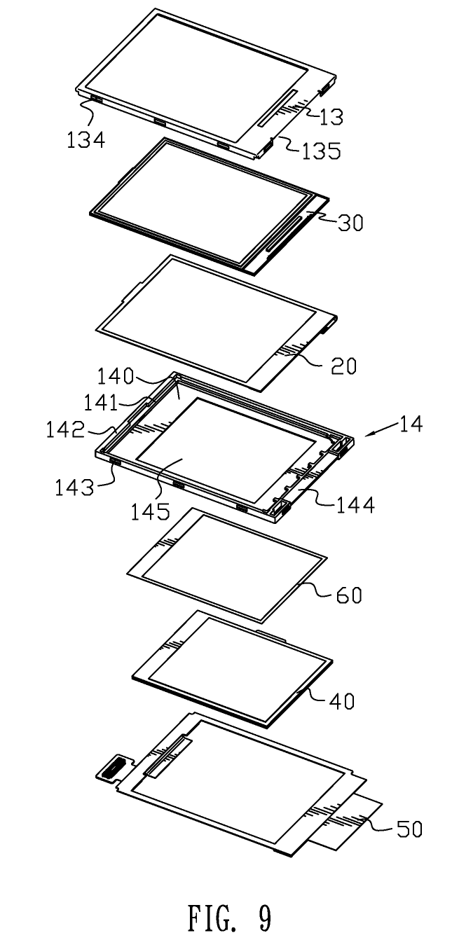

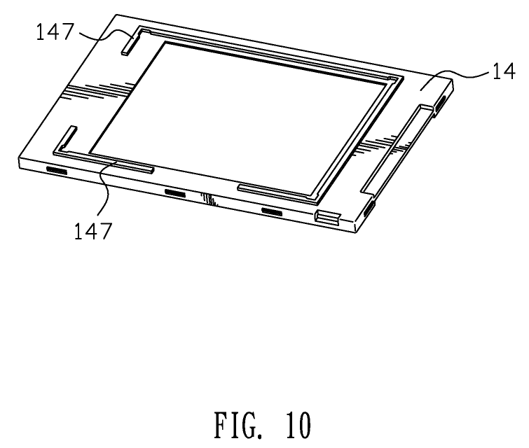

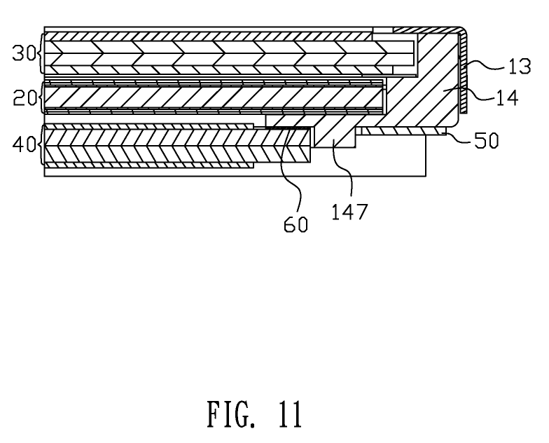

Referring to FIGS. 8-11, a second embodiment of a dual-screen display device 10 is disclosed. The dual-screen display device 10 includes a frame assembly, a backlight module 20, a main screen panel 30, a twin adhesive tape 60, a secondary screen panel 40 and a main circuit board 50. The frame assembly includes a third frame 13 which is similar in construction as that described in the first embodiment and a main frame 14. The second embodiment is similar to the first embodiment, and the difference therebetween is that the first frame 11 and the second frame 12 of the first embodiment are substituted for the main frame 14 of the second embodiment. The main frame 14 made of resin material has a base board 140 in rectangular board shape. An opening 145 is defined in the base board 140. A plurality of resisting walls 147 extends downward from the backside of the base board 140. Edges of the base board 140 extend vertically upward to form first side walls 141, and then outer edges of the first side walls 141 extend upward to form second side walls 142 respectively. A plurality of bulges 143 is arranged on the first and second side walls 141, 142 corresponding to slots 134 defined on the third frame 13. The first side wall 141 and the second side wall 142 define a main opening 144 passing therethrough and corresponding to a notch 135 defined on the third frame 13.

When the dual-screen display device 10 of the second embodiment is assembled, the backlight module 20 and the main screen panel 30 are received in a space which is defined by the main frame 14 and the third frame 13. The secondary screen panel 40 resists the resisting walls 147 and is glued on the backside of the main frame 14 by the twin adhesive tape 60.

According to above description, since the edges of the secondary screen panel 40 resist the resisting walls 117, 147 and are glued on the backside of the base board 110, 140, the process of assembling the secondary screen panel 40 on the first frame 11 or the main frame 14 is simple. It is obvious that the assembly process of the secondary screen panel 40 in the frame assembly doesn't need any auxiliary tool, so the cost of manufacturing the dual-screen display device 1, 10 is reduced and the time of assembling the dual-screen display device 1, 10 is cut down.

Embodiments of the present invention have been discussed in detail. However, these embodiments are merely a specific example for clarifying the technical contents of the present invention and the present invention is not to be construed in a restricted sense as limited to these specific examples. Thus, the spirit and scope of the present invention are limited only by the appended claims.

What is claimed is:

1. A display device, comprising:
a frame assembly;
a first screen panel received in the frame assembly;
a second screen panel electrically coupled with the first screen panel and hold by the frame assembly; and
a main circuit board electrically connected with both the first and second screen panels, the main circuit board defining a receiving opening upon which an underside of the second screen panel is rested, a gap being defined between the second screen panel and the main circuit board when the underside of the second screen panel is rested upon the receiving opening of the main circuit board;
wherein the frame assembly comprises at least one positioning member configured to be inserted into the gap for restraining the second screen panel in place.

2. The display device as set forth in claim 1, wherein the frame assembly comprises a first frame, a second frame received on the first frame and a third frame covered on the second frame, the positioning member is a resisting wall extended vertically from the first frame, and one sidewall of the resisting wall is adhesive for adhering the second screen panel thereto.

3. The display device as set forth in claim 1, wherein the frame assembly comprises at least two frames, wherein one of the frames is covered on the other frame, the positioning member is a resisting wall extended vertically from the covered frame, and the secondary screen panel is fixed onto the covered frame using twin adhesive tape.

4. The display device as set forth in claim 1, wherein the frame assembly defines an auxiliary slot, the positioning member extends from an outer edge of the corresponding auxiliary slot and shows a long and narrow piece shape.

5. The display device as set forth in claim 1, further comprising a backlight module received in the frame assembly and located between the first screen panel and the second screen panel.

6. The display device as set forth in claim 1, wherein the main circuit board has a first connecting portion that is received in an opening defined on the frame assembly for electrically connecting with the first screen panel.

7. The display device as set forth in claim 1, wherein the main circuit board has a second connecting portion at an end thereof for electrically connecting with the second screen panel.

8. The display device as set forth in claim 1, wherein the second screen panel is positioned on the frame assembly by using a twin adhesive tape glued on the frame assembly.
